(19) United States
(12) Patent Application Publication
(10) Pub. No.: US 2005/0095809 A1
(43) Pub. Date: May 5, 2005

(54) Method of film-forming transparent electrode layer and device therefor

(76) Inventors: Yuji Nakayama, Saitama (JP); Satoshi Shiozaki, Saitama (JP)

Correspondence Address: FULBRIGHT AND JAWORSKI L L P;PATENT DOCKETING 29TH FLOOR, 865 SOUTH FIGUEROA STREET, LOS ANGELES, CA, 900172576, US

(21) Appl. No.: 10/483,925

(22) PCT Filed: Jul. 12, 2002
(86) PCT No.: PCT/JP02/07110

(30) Foreign Application Priority Data
Jul. 18, 2001 (JP) 2001-252127
Nov. 13, 2001 (JP) 2001-385275
Jun. 4, 2002 (JP) 2002-199291

(51) Int. Cl. H01L 21/76

(52) U.S. Cl. 438/454

(57) ABSTRACT

A method and apparatus for forming a transparent electrode layer of a thin-film compound semiconductor solar cell by using only a direct-current sputtering system, wherein a preliminary layer is formed in a first process by direct-current sputtering from a target by supplying thereto a specified low electric power preset so as not to damage the substrate by sputters and a complete layer is deposited thereon in a second process by sputtering from the same target by supplying a high electric power. The same layer is also formed by direct-current sputtering from a pair of oppositely disposed targets of the same material. The method and apparatus are capable of easily forming a high quality transparent electrode layer at an increased speed.

### BACKGROUND OF THE INVENTION

The present invention relates to a method and an apparatus for forming by a sputtering technique a transparent electrode layer of a thin-film compound semiconductor solar cell.

FIG. 1 shows a basic structure of a thin-film solar cell fabricated from a compound semiconductor, which comprises a SLG (soda lime glass) substrate 1 having subsequently formed thereon a molybdenum (Mo) rear-side positive electrode layer 2, a CIGS thin-film light absorbing layer 3 (p-type), a ZnS buffer layer 4 (n-type) and a transparent negative electrode layer 5.

In the thin-film compound-semiconductor solar cell, the transparent electrode layer 5 is required to have a high transparency and a low resistance to effectively collect light falling on the solar cell and is usually formed by a sputtering method since it is advantageous from the view point of securing the mass productivity and the quality of the product.

However, in the case of sputtering a thin layer of a transparent electrode 5, particles sputtered from a target may damage by their impact energy a buffer layer 4 affecting a junction plane between the buffer layer 4 and the light absorbing layer 3. To prevent the buffer layer 4 from being damaged by sputters, it is preferable to form a transparent electrode layer by using a RF sputtering method with a reduced electric power, which method is, however, accompanied by a considerable decrease in speed of forming the layer.

In view of the above, a conventional process disclosed in Japanese Laid-Open Patent Publication No. Hei-11-284211 is devised to form a transparent electrode layer 5 in such a manner that a first conductive layer functioning as a protection layer for the junction plane is formed by the RF sputtering method with a low electric energy and then a second conductive layer is formed thereon by the direct-current (DC) sputtering method at an increased speed with an increased electric power to produce a transparent electrode layer 5 composed of the first and second conductive layers.

However, the RF sputtering method cannot increase the speed of forming the transparent electrode layer 5. This is a bottleneck in solving the problem of high-speed mass production of the solar cells. The combination of RF and DC sputtering methods requires the provision of two kinds of power supply sources which must be switched over to each other, resulting in complicating the power supply control system. In other words, the process of forming a transparent electrode layer of a solar cell by using both the RF sputtering method and the DC sputtering method can not sufficiently increase the layer forming speed and complicates the power supply sources and the power supply control system.

### SUMMARY OF THE INVENTION

Accordingly, an object of the present invention is to provide a transparent electrode layer forming method capable of easily producing a high-quality transparent electrode layer of a thin-film compound semiconductor solar cell at a high forming speed by sputtering particles of material from a target by supplying electric power from a DC power supply source only, whereby a transparent electrode layer is formed in two sputtering processes: the first process forms a precursory layer by sputtering from a target by supplying thereto a DC electric power preset to a specified low energy not to cause any sputter damage affecting the quality of the solar cell product and the second process forms a complete transparent electrode layer by sputtering from the same target by supplying thereto a higher DC electric power.

The present invention also provides an apparatus for forming a transparent electrode layer or a substrate with particles sputtered from a target in a vacuum bath by stepwise changing a DC current applied to the target from a DC power supply source by means of a controller capable of controlling the DC power supply in steps in a range from a low power to a high power.

Another object of the present invention is to provide a method of forming a transparent electrode layer of a thin-film compound semiconductor solar cell, which is capable of easily forming a transparent electrode layer on a substrate at a high speed by sputtering from a pair of targets of the same material disposed opposite to each other by applying electric power from a DC power supply source only without damaging the substrate by sputters.

Another object of the present invention is to provide a method of forming a transparent electrode layer of a thin-film compound semiconductor solar cell, whereby a transparent electrode layer is formed in two sputtering processes: the first process forms a precursory layer by sputtering from a pair of targets of the same material disposed opposite to each other in order to shorten the time of forming the precursory layer and the second process forms a complete transparent electrode layer by sputtering from a single target supplied with a high electric power from a DC power supply source.

The present invention also provides an apparatus for forming a transparent layer on a substrate with particles sputtered from a pair of targets of the same material by changing step-by-step a DC electric power applied to the targets by means of a controller capable of controlling the DC power supply in steps in a range from a low power to a high power.

### BRIEF DESCRIPTION OF THE DRAWINGS

FIG. 1 shows a basic structure of a solar cell of general compound semiconductors in cross section.

FIG. 2 is a schematic construction view of an exemplary apparatus for forming a transparent electrode layer of a solar cell according to the present invention.

FIG. 3 is a schematic construction view of an exemplary industrial apparatus for forming transparent electrode layers of solar cells according to the present invention.

FIG. 4 is a graph showing conversion efficiency characteristics of transparent electrode layers based on results of the first experiment conducted by changing conditions for forming transparent electrode layers on respective substrates.

FIG. 5 is a graph showing conversion efficiency characteristics of transparent electrode layers based on results of the second experiment conducted by changing conditions for forming transparent electrode layers on respective substrates.

FIG. 6 illustrates a process of fabricating a transparent electrode layer according to the present invention.

FIG. 7 show a state of forming a transparent electrode layer on a substrate with sputters from a pair of targets disposed opposite to each other according to the present invention.

FIG. 8 is a schematic construction view of another exemplary industrial apparatus for fabricating transparent electrode layers of solar cells according to the present invention.

FIG. 9 is a graph showing conversion efficiency characteristics of transparent electrode layers formed by the third experiment by changing conditions for forming transparent electrode layers on respective substrates by opposite target sputtering.

FIG. 10 is a graph showing conversion efficiency characteristics of transparent electrode layers formed by the fourth experiment by changing conditions for forming transparent electrode layers on respective substrates by opposite target sputtering.

### PREFERRED EMBODIMENT OF THE INVENTION

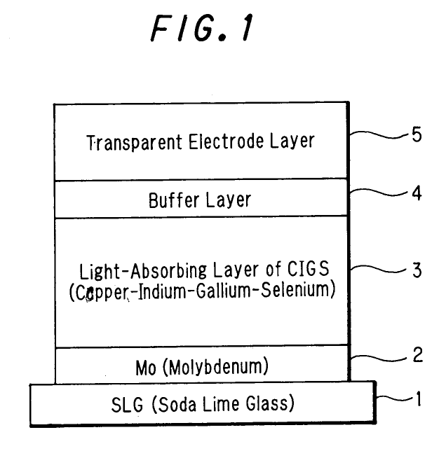

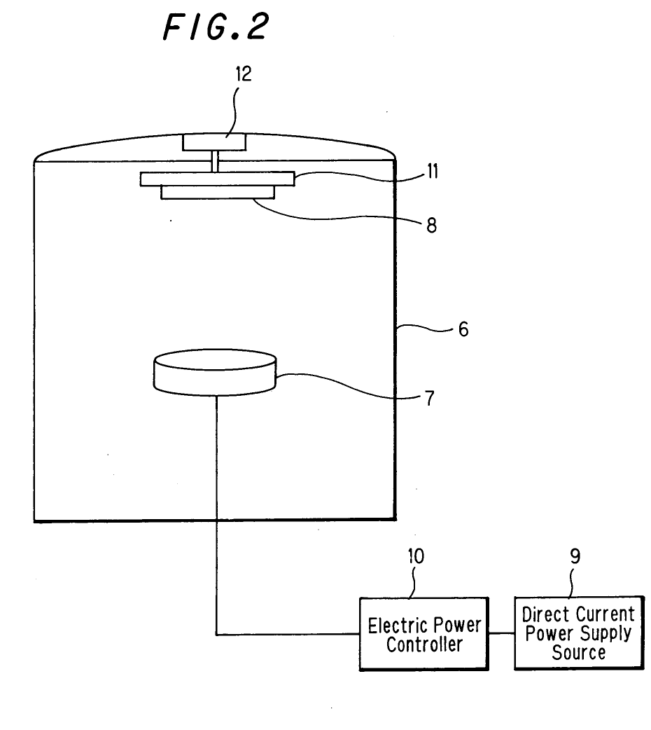

FIG. 2 is a schematic construction view of an exemplary apparatus for forming a transparent electrode layer of a solar cell according to the present invention. This sputtering apparatus comprises a vacuum chamber 6 in which a target 7 and a composite substrate 8 are disposed, and a DC power supply source 9 with a DC power supply controller 10, wherein a DC current from the DC power supply source 9 through the controller is supplied to the target 7 to sputter particles of material for forming a transparent electrode layer on a composite substrate 8 by changing in steps the electric power supplied to the target in a range from a lower level to a high level by means of the controller 10. In this apparatus, the substrate 8 is mounted on a holder 11 which is rotated by a rotary mechanism 12 in order to effectively form an evenly thick transparent electrode layer on the top surface of the substrate 8. The holder 11 incorporates a heater for heating the substrate 8. The composite substrate 8 consists of a soda lime glass substrate (base) 1 on which a molybdenum (Mo) electrode layer 2, a thin-film CIGS light absorbing layer 3 and a ZnS buffer layer 4 have been deposited in advance in the described order, as shown in FIG. 1. The Mo electrode layer was deposited on the substrate by a sputter deposition method, the light absorbing layer was deposited on the Mo electrode layer by any of several methods (evaporation, sputter deposition, evaporation plus treatment with selenium, sputter deposition plus treatment with selenium and metallization), and the buffer layer was deposited by CBD method. The target 7 of ZnO:X (X being Ga, Al, In or B) is used.

When forming a transparent electrode layer, the vacuum chamber 6 is evacuated to a specified vacuum of about 5×10⁻⁵ Pa and the substrate 8 is heated to a specified temperature (in a range of room temperature to 300° C.). It is desirable to keep the substrate 8 at a constant regulated temperature in a range of 200° C. to 300° C. so that a transparent electrode layer may be well formed on the substrate with no fear of damaging, by heat, the light absorbing layer 3 and the buffer layer 4 of the substrate. There may be a case that hydrogen gas or oxygen gas whose concentration is of no more than 2.0% may be introduced into the vacuum chamber in order to mutely control the composition of a transparent electrode layer to be fabricated. The introduction of the gas is intended to maintain a specified stoichiometric coefficient of a ZnO-layer formed as a transparent electrode layer of the composite substrate and/or to remove the oxygen by reduction.

According to the present invention, the transparent electrode layer is formed by the method which comprises the first sputtering process for depositing material from a target 7 by supplying thereto a specified low electric power from a DC power supply source under the control of the electric power control unit 10 so as not to damage by sputters the top surface of the composite substrate and the second sputtering process for completing a transparent electrode layer on the composite substrate by sputtering material from the same target by supplying thereto a higher electric energy from the same DC power supply source. In practice, the first sputtering process is performed by supplying the target 7 of about 480 cm³ with an electric power of 300 to 1000 W (0.6-2.1 W per 1 cm²) to form a precursory film of 0.02 to 0.2 microns in thickness. In general, the time necessary for forming a layer can be reduced with an increase in electric energy to be supplied to the target 7. However, if high power is supplied to the target from the beginning of forming a transparent precursory layer on the substrate, intensive sputters may damage the interfacial plane of the buffer layer 4 previously formed on the composite substrate as described before. Therefore, the electric power is strictly controlled to a low power value at which no sputter damage can arise. A thinner precursory layer can be formed faster with the same low sputtering power. However, the precursory layer must be thick enough to protect a top surface of the buffer layer 4. Its thickness depends on the quality of the buffer layer 4 and may be, in practice, about 0.08 microns.

In the second sputtering process, the target is supplied with a high electric power of 1000 to 5000 W (2.1 to 10.4 W per unit area of 1 cm²) to fabricate a transparent electrode layer of 0.3 to 3.0 microns in total thickness. The total thickness of the transparent electrode layer to be fabricated must be decided in view of material of the target and the size of a final solar cell product. In the second process, sputtering can be performed by supplying a high electric power to the target 7 since the buffer layer 4 is protected with the precursory film deposited thereon by the first sputtering process. However, the excessive high power must be avoided since it makes electric discharge of the target 7 unstable since the target can be easily oxidized. It is possible to form a transparent electrode layer by changing in multiple steps from a low to higher power at the DC power supply source under the control of the power supply controller 10.

According to the present invention, it is possible to fabricate a transparent electrode layer by only DC sputtering in two steps, i.e., a precursory layer for protecting an interfacial surface of a buffer layer 4 formed on the top of a composite substrate is deposited by DC sputtering with a low DC power (in the first sputtering process) and then a final transparent electrode layer is formed by DC sputtering with a high DC power (in the second sputtering process), thus realizing the formation of a high quality film of the transparent electrode on the composite substrate at a high speed with no affection of sputters to the buffer layer.

A solar cell having a transparent electrode layer formed by the method according to the present invention is comparable in conversion efficient to a solar cell having a transparent electrode layer formed by a conventional RF sputtering method and can offer an advantage over the latter by the fact that the time necessary for forming by the present invention method a transparent electrode layer of the same thickness corresponds to 40% of the time taken by the RF sputtering method.

FIG. 3 illustrates an exemplary industrial apparatus for fabricating a transparent electrode layer 5, which is used in a line of mass production of solar cells. This apparatus comprises a substrate feeding chamber P11 with an entrance door 13 for storing therein a number of composite substrates 14 (soda lime glass substrates 1, each having a molybdenum (Mo) electrode layer 2, a light absorbing layer 3 and a buffer layer 4 formed thereon in the described order) to be subsequently fed to the process, a working chamber P21 with an evacuating system, wherein a substrate 14 fed from the substrate feeding chamber P11 is transported, while being heated by a heater 15, to a first DC sputtering portion PS111 for forming a precursory transparent electrode layer on the substrate 14 by DC sputtering material from a target supplied with a low electric power and then transported to a second DC sputtering portion PS21 for forming a complete transparent electrode layer on the substrate 14 by DC sputtering from the target supplied with a high electric power, and a substrate delivering chamber P31 for temporarily storing therein substrates 14′ (each substrate has a transparent electrode layer formed thereon) and discharging the substrates 14′ through the outlet door 16 after a venting operation. The substrate feeding chamber P11, the working chamber P21 and the substrate delivering chamber P31 communicate with each other in a tightly enclosed state. When forming a transparent electrode layer on a substrate 14 by sputtering, the inside of the apparatus is evacuated in advance to a specified vacuum (about 5×10⁻⁵ Pa) and the substrate 14 is heated by a heater 15 and maintained at a specified temperature (in a range of a room temperature to 300° C.). The condition of forming the transparent electrode layer may be improved by heating the substrate to a higher temperature. However, the temperature of the substrate 14 should be lower than a temperature at which the light absorbing layer 3 and the buffer layer 4 of the substrate may be damaged by heat (such a fear may arise at a temperature of higher than 300° C.). In view of the above, it is preferable to maintain the substrate at a temperature in a range of 200° C. to 300° C. There may be a need of introducing hydrogen or oxygen gas in an amount of no more than 2.0% into a sputtering chamber to mutely control a content of the layer to be formed on the substrate. This is intended to add oxygen necessary for maintaining a stoichiometric ratio of a ZnO film to be formed as a transparent electrode layer on a substrate and to remove oxygen by reduction.

Table 1 below indicates the correlation between power conversion efficiencies of solar cells fabricated on a plurality of substrates and discharge densities for first depositions of their transparent electrode layers, which were obtained by experiments with the solar cells fabricated under the following common conditions.
Common Conditions:
Light absorbing layer: CIGS layer formed by selenization method
Buffer Layer: ZnS
Transparent electrode target: ZnOAl (Al203=2 wt %)
Ultimate vacuum: 8×10 E⁵ Pa
Film forming pressure: 0.5 Pa
Sputter gas: 100% Argon

Substrate temperature: 150° C.

TABLE 1

| | 1st layer | | | | 2nd layer | | | | |
|---|---|---|---|---|---|---|---|---|---|
| Subst. | | | | Density | | | | Density | Conversion |
| No. | Method | Thick. Å | Output W | W/cm² | Method | Thick. Å | Output W | W/cm² | Efficiency % |
| 1 | DC | 6000 | 2000 | 4.11 | | | | | 7.5 |
| 2 | RF | 1000 | 600 | 1.23 | DC | 5000 | 2000 | 4.11 | 14.5 |
| 3 | RF | 1000 | 2000 | 4.11 | DC | 5000 | 2000 | 4.11 | 14.8 |
| 4 | DC | 1000 | 600 | 1.23 | DC | 5000 | 2000 | 4.11 | 14.5 |
| 5 | DC | 1000 | 1000 | 2.06 | DC | 5000 | 2000 | 4.11 | 14.6 |
| 6 | DC | 1000 | 2000 | 4.11 | DC | 5000 | 2000 | 4.11 | 7.5 |
| 7 | DC | 1000 | 2500 | 5.14 | DC | 5000 | 2000 | 4.11 | 4.2 |
| 8 | DC | 1000 | 3000 | 6.17 | DC | 5000 | 2000 | 4.11 | 0.0 |

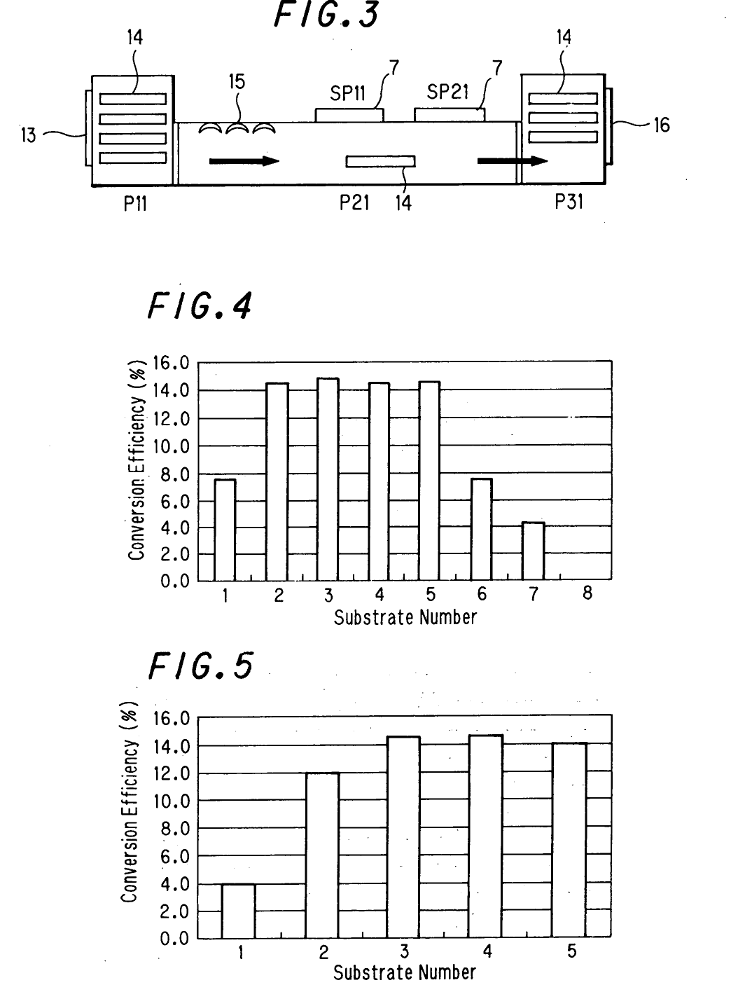

FIG. 4 shows the characteristics of power conversion efficiency of respective solar cell substrates set forth in Table 1.

The Experiment Results Prove That:

The substrate No. 1 with a single transparent electrode layer formed by direct-current sputtering from a target with a high power applied thereto possesses low conversion efficiency, thereby decreasing the photoelectric conversion characteristics of the solar cell product.

The substrates Nos. 2 and 3 on which a transparent electrode film was formed by forming a first layer by the conventional radio-frequency (RF) sputtering method and then by forming a second layer by the direct-current sputtering method show increased conversion efficiencies with a decreased sputter damage, thereby achieving high performance characteristics of the solar cell product.

The substrates Nos. 4 and 5 each having a transparent electrode film formed by depositing a first layer on a buffer layer by direct-current sputtering with a low electric power (discharge density of no more than 2.1 W/cm²) and by depositing a second layer on the first layer by direct-current sputtering with a high electric power show improved conversion efficiencies (high solar cell performance characteristics) comparable to those of the substrates Nos. 2 and 3.

The substrates Nos. 6-8 each having a transparent electrode layer formed by depositing a first layer on a buffer layer by direct-current sputtering with a high electric power (discharge density of no less than 4.1 W/cm²) and by depositing a second layer on the first layer by direct-current sputtering with a high electric power have decreased conversion efficiencies (lower solar cell performance characteristics). Accordingly, based on the experimental results with the substrates as to the effect of discharge densities of material for forming the first layers to the performance characteristics of the solar cell products, the substrates Nos. 4 and 5 are the most suitable samples of forming transparent electrode layers.

In Table 2, there are shown results of experiments of forming transparent electrode layers on respective substrates by depositing their first layers of different thickness values by using the suitable discharge density and the above-mentioned common conditions to obtain the correlation of the first layer of each transparent electrode layer of each substrate and the power conversion efficiency of the solar cell product with the same transparent electrode layer.

TABLE 2

| | 1st layer | | | | 2nd layer | | | | |
|---|---|---|---|---|---|---|---|---|---|
| Subst. | | | | Density | | | | Density | Conversion |
| No. | Method | Thick. Å | Output W | W/cm2 | Method | Thick. Å | Output W | W/cm2 | Efficiency % |
| 1 | DC | 150 | 600 | 1.23 | DC | 5850 | 2000 | 4.11 | 3.8 |
| 2 | DC | 300 | 600 | 1.23 | DC | 5700 | 2000 | 4.11 | 12.0 |
| 3 | DC | 600 | 600 | 1.23 | DC | 5400 | 2000 | 4.11 | 14.5 |
| 4 | DC | 1000 | 600 | 1.23 | DC | 5000 | 2000 | 4.11 | 14.6 |
| 5 | DC | 1500 | 600 | 1.23 | DC | 4500 | 2000 | 4.11 | 14.0 |

FIG. 5 indicates the characteristics of conversion efficiency of respective solar cell substrates set forth in Table 2. The results of the experiments are as follows:

The substrates each having a transparent electrode layer formed thereon by depositing a first film of not more than 300 Å in thickness have decreased conversion efficiencies, thereby decreasing the performance of the solar cell products. In contrast, the substrates each having a transparent electrode layer whose first layer is of no less than 600 Å in thickness can possess increased conversion efficiencies, thereby achieving improved performance characteristics of the solar cell products. In addition, it is noted that the conversion efficiencies of the substrates with the first layer of 600 to 1500 Å are almost the same. On the basis of the experimental results, it is preferable to form the first layer composing the transparent electrode layer to be of a thickness in a range of 600 to 1000 Å in view of productivity of solar cell products.

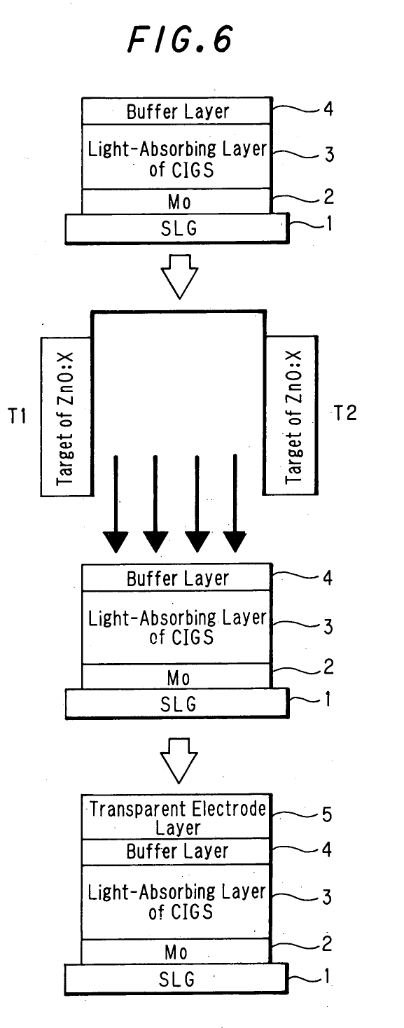

According to the present invention, as shown in FIG. 6, a composite substrate composed of a soda-lime glass substrate 1 having a molybdenum electrode layer 2, a light absorbing layer 3 and a buffer layer 4 preformed thereon in the described order is used for further forming on the top thereof a transparent electrode layer 5 by sputtering from a pair of oppositely disposed targets T1 and T2 of the same material of ZnO:X (X is Ga, Al In or B). In the opposite targets type sputtering apparatus, a magnetic field is applied in such a way as to enclose a space between the opposite targets T1 and T2 and to capture sputter plasma therein, thus allowing particles sputtered from the opposite targets to deposit onto the substrate disposed on one side facing the open space. A DC power supply source is used to supply electric power to the targets.

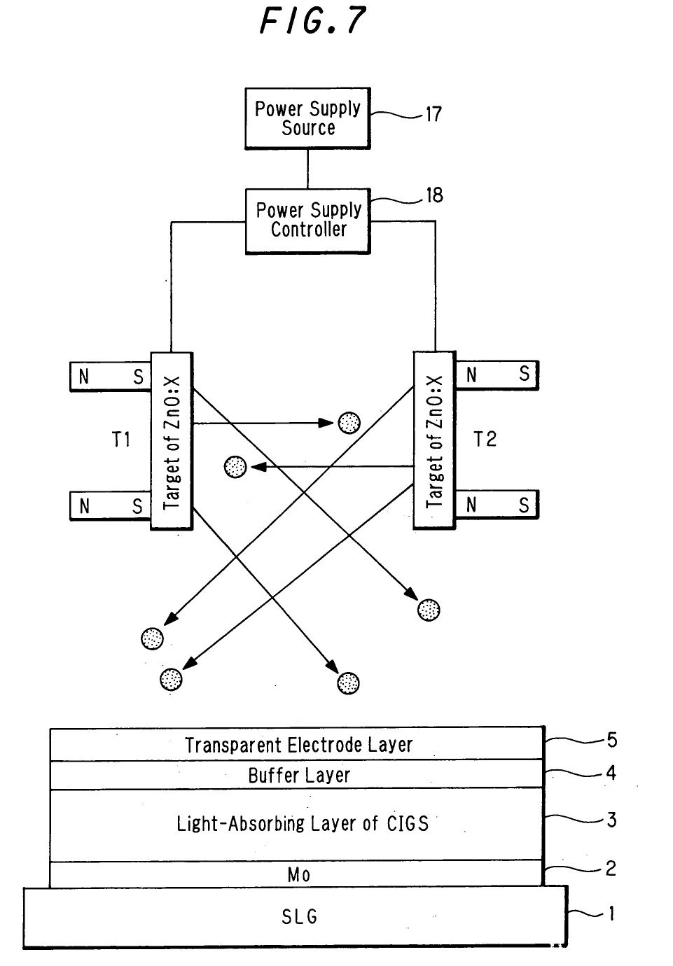

FIG. 7 illustrates the state of particles sputtered from the opposite targets T1 and T2 of ZnO:X when forming a transparent conducting layer 5 by depositing particles onto the buffer layer 4 of the substrate. When the opposite targets T1 and T2 were simultaneously excited, particles are sputtered from paired targets and, at this time, a large portion of particles deposit directly on the buffer layer 4 of the composite substrate and a small portion of them reach the surfaces of the opposite targets.

The opposite target type sputtering apparatus is capable of changing conditions of forming layers by adequately adjusting the electric power supply to the respective targets T1 and T2. Thus, the apparatus can form a high-quality transparent conductive layer 5 on the substrate at a high speed at a room temperature.

Normal DC sputtering (magnetron sputtering) can be carried out by using a single target and a composite substrate disposed opposite to the target. In this arrangement, negative ions produced in the sputtering process are accelerated by the effect of a clone force to collide against the top surface of the substrate, resulting in damaging the surface thereof. To avoid this, it is necessary to first form a protecting film on the top surface of the substrate by a RF sputtering method by exciting the target with low electric power and then to form at an increased speed a complete transparent electrode layer on the protected surface of the substrate by a DC sputtering method.

In contrast, in the opposite target type sputtering apparatus, a substrate is disposed on the side facing an open space between the opposite targets T1 and T2 and placed with its surface parallel with a electromagnetic field, whereby the collision of negative ions against the substrate surface can be effectively reduced. Namely, it becomes unnecessary to form a protecting film on the substrate.

In the case of forming a transparent electrode layer 5 on a buffer layer 4 of the composite substrate by normal DC sputtering, it is needed to previously form the buffer layer 4 of not less than 500 Å in thickness so as to protect against possible sputter damage affecting a junction plane with a light absorbing layer 3 of the substrate. In contrast, the opposite target type sputtering can form a transparent electrode layer on a buffer layer 4 of not more than 500 Å with no affection of sputters thereto, thus contributing to reduction of a total thickness of a solar cell product.

The solar cell having a transparent electrode layer 5 formed at an increased speed by the above-described opposite target sputtering method according to the present invention can achieve higher photoelectric conversion efficiency than that of a solar cell having a transparent electrode layer formed at the same speed by a normal direct-current sputtering method. Furthermore, in comparison with a solar cell having a transparent electrode layer formed only by a RF sputtering method for the purpose of reducing the possibility of damaging by sputters, the solar cell having a transparent electrode layer 5 formed by the opposite target sputtering method according to the present invention possesses equivalent photoelectric conversion efficiency and differs by a twice higher speed of forming the transparent electrode layer.

The time necessary for forming a transparent electrode layer 5 of the solar cell by the opposite target sputtering can be shortened by increasing electric power to be supplied to a pair of targets. However, in practice, it is preferable to apply a relatively low electric power to the targets at an earlier stage of forming a transparent electrode layer 5 in order to obtaining a high quality of the layer with no sputter damage of the buffer layer. In the earlier sputtering stage, a film is formed to be of about 0.08 microns in thickness, which can protect the interfacial plane of the buffer layer 4 of the substrate. Then, the electric power to the targets can be increased. However, it is noted that an excessive increase of the electric power to the targets T1 and T2 may cause the discharge from T1 and T2 to be unstable because the targets are of oxide material. To change the DC electric power to the targets from low for the earlier stage to high for the normal stage of forming the transparent electrode layer, a DC power supply source 17 is, as shown in FIG. 7, provided with a power supply regulator 18 which is capable of gradually changing the electric power to the targets T1 and T2 under the control from a control unit (not shown). The electric power supply to the targets T1 and T2 may be changed over in two steps, i.e., for earlier sputtering and normal sputtering, or gradually in multiple steps in progress of formation of the layer. To reduce damaging by sputters the buffer layer 4, it is possible to form an under-layer by opposite target sputtering in the first stage and then complete a transparent electrode layer at an increased speed in the second stage (or multiple stages) by DC (magnetron) sputtering from a single target by applying thereto a higher electric power.

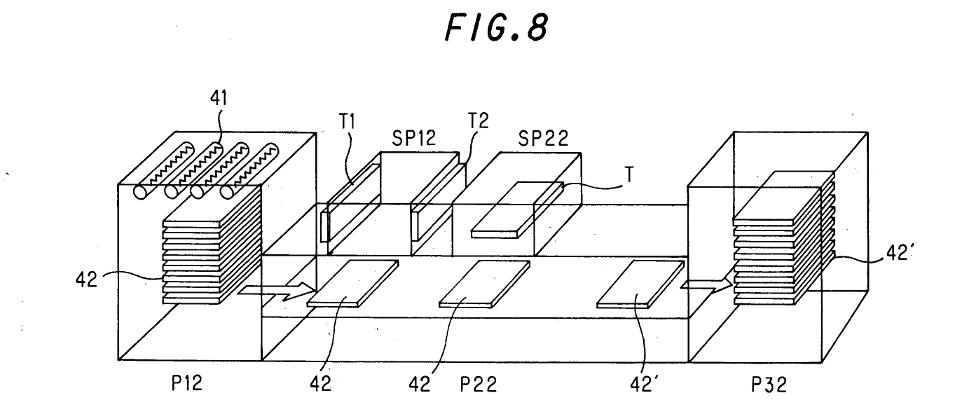

FIG. 8 illustrates an exemplary industrial apparatus for fabricating a transparent electrode layer 5, which is used in a line of mass production of solar cells. This apparatus comprises a substrate feeding chamber P12 with a heater 41 for storing therein at a constant temperature a number of composite substrates 42 (soda lime glass substrates 1, each having a molybdenum (Mo) electrode layer 2, a light absorbing layer 3 and a buffer layer 4 formed thereon in the described order), a working chamber P22 with an evacuating system, wherein a substrate fed from the substrate feeding chamber P12 is transported to an opposite target sputtering portion SP12 where it is subjected to formation of the first layer thereon and then to a single target DC sputtering portion SP22 where it is subjected to formation of the final transparent electrode layer by applying high electric power to the single target T, and a substrate cooling chamber P32 for temporarily storing therein substrates 42′ (each substrate has a transparent electrode layer formed thereon) and cooling them. When forming a transparent electrode layer on a substrate 42 by sputtering, the inside of the apparatus is evacuated in advance to a specified vacuum (about 5×10⁻⁵ Pa) and the substrate 42 is heated by a heater 41 and maintained at a specified temperature (in a range of a room temperature to 300° C.). The condition of forming the transparent electrode layer may be improved by heating the substrate to a higher temperature. However, the temperature of the substrate should be lower than a temperature at which the light absorbing layer 3 and the buffer layer 4 of the substrate may be damaged by heat (such a fear may arise at a temperature of higher than 300° C.). In view of the above, it is preferable to maintain the substrate at a temperature in a range of 200° C. to 300° C. There may be a need of introducing hydrogen or oxygen gas in an amount of no more than 2.0% into the sputtering chamber to mutely control a content of the layer to be formed on the substrate. This is intended to add oxygen necessary for maintaining a stoichiometric ratio of a ZnO film to be formed as a transparent electrode layer on a substrate and to remove oxygen by reduction.

Table 3 indicates the correlation between power conversion efficiencies of solar cells fabricated on a plurality of substrates and discharge densities for first depositions of their transparent electrode layers, which data were obtained by experiments with the solar cells fabricated under the following common conditions:
Light absorbing layer: CIGS layer formed by selenization method
Buffer Layer: ZnS
Target: ZnOAI (Al₂O₃₌₂ wt %)
Thickness of transparent electrode layer: First layer 1000 Å, Second layer 6500 Å
Ultimate vacuum: 8×10 E ⁵ Pa
Film forming pressure: 0.5 Pa
Sputter gas: 100% Argon

Substrate temperature: 250° C.

TABLE 3

| | 1^{st} layer | | | 2^{nd} layer | | | |
|---|---|---|---|---|---|---|---|
| | | | Density | | | Density | Conversion |
| No. | Method | Output W | W/cm2 | Method | Output W | W/cm2 | Efficiency % |
| 1 | Magnetron RF (conv.) | 800 | 0.7 | DC | 3300 | 3.0 | 12.5 |
| 2 | Magnetron RF (conv.) | 2500 | 2.3 | DC | 3300 | 3.0 | 2.3 |
| 3 | Magnetron Target (conv.) | 1000 | 2.8 | DC | 3300 | 3.0 | 12.5 |
| 4 | Magnetron Target (conv.) | 1250 | 3.5 | DC | 3300 | 3.0 | 12.3 |
| 5 | Magnetron Target (conv.) | 1500 | 4.2 | DC | 3300 | 3.0 | 12.2 |
| 6 | Magnetron Target (conv.) | 2000 | 5.6 | DC | 3300 | 3.0 | 9.8 |
| 7 | Magnetron Target (conv.) | 3000 | 8.4 | DC | 3300 | 3.0 | 10.0 |

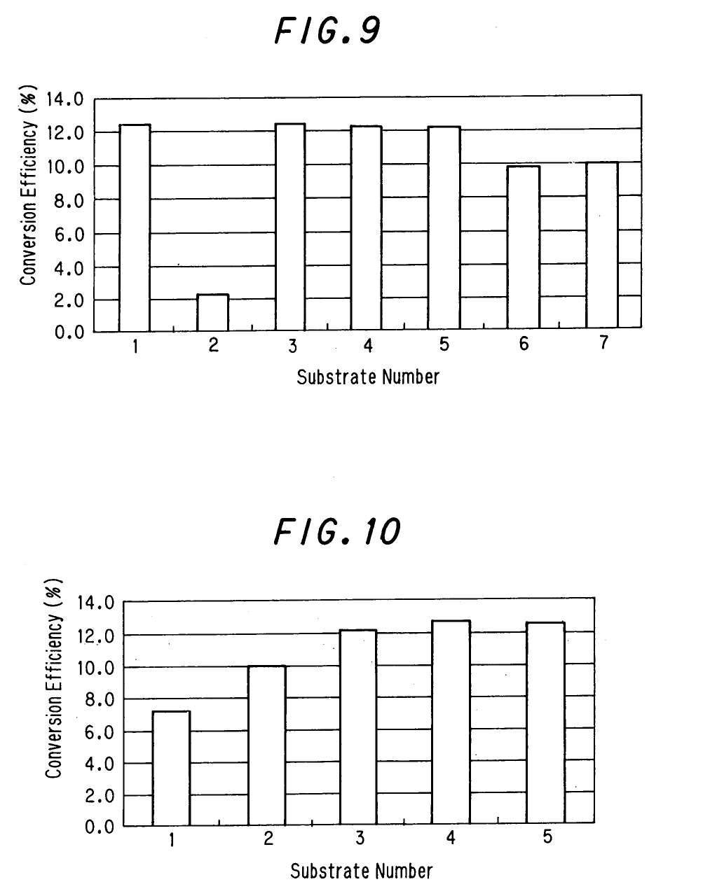

FIG. 9 indicates the characteristics of conversion efficiency of respective solar cell substrates set forth in Table 3.

As is apparent from the experiment results, the method of sputtering from opposite targets can form transparent electrode layers with reduced affection of DC sputters on an average efficiency even by applying electric power higher than that applied by the conventional method. The samples 1 (formed by conventional magnetron sputtering) and 3 (formed by DC sputtering from opposite targets) have conversion efficiencies comparable with each other and the latter could be formed at an increased speed higher than that of the former by a factor of 2.5. The DC sputtering from the opposite targets can be applied at a further increased electric power with no decrease in the conversion efficiency of the product. A desirable electric power to the targets for forming a transparent electrode layer is estimated at about 1500 W (4.2 W/cm²) for sample 5 in view of the trade-off relation between the layer-forming speed and the stability of discharge from the targets.

Table 4 indicates the correlation between conversion efficiencies of samples and thickness of a first film of a transparent electrode layer, which were obtained by experiments with the samples fabricated under the following common conditions:
Light absorbing layer: CIGS layer formed by selenization method
Buffer Layer: ZnS
Target: ZnOAl (Al203=2 wt %)
Thickness of transparent electrode layer: total 7500 Å
Ultimate vacuum: 8×10 E ⁵ Pa
Film forming pressure: 0.5 Pa
Sputter gas: 100% Argon

Substrate temperature: 250° C.

TABLE 4

| | 1^{st} layer | | | 2^{nd} layer | | | Conversion |
|---|---|---|---|---|---|---|---|
| No. | Method | Thickness Å | Output W | Method | Thickness Å | Output W | Efficiency % |
| 1 | Opposite Target DC | 250 | 1000 | DC | 7250 | 3300 | 7.5 |
| 2 | Opposite Target DC | 500 | 1000 | DC | 7000 | 3300 | 10.0 |
| 3 | Opposite Target DC | 750 | 1000 | DC | 6750 | 3300 | 12.2 |
| 4 | Opposite Target DC | 1000 | 1000 | DC | 6500 | 3300 | 12.6 |
| 5 | Opposite Target DC | 1250 | 1000 | DC | 6250 | 3300 | 12.5 |

FIG. 10 shows the characteristics of conversion efficiencies of the respective substrates set forth in Table 4.

The results of the experiments indicates it is preferable to form a first film as thin as possible in order to shorten the time of forming a total transparent electrode layer. As is apparent from the experimental results, conversion efficiencies of samples having a first layer of not less than 750 Å in thickness are about the same while conversion efficiencies of samples having a first layer of not more than 500 Å considerably decreases. This means that a first film of a transparent electrode layer is desirably deposited in thickness of 750 Å.

### Industrial Applicability

As is apparent from the foregoing, the transparent electrode layer forming method according to the present invention can produce a transparent electrode layer of a thin-film compound semiconductor solar cell by first depositing a first thin layer on a substrate by sputtering from a target by supplying thereto a specified low electric power from a DC power supply source so as not to damage the top surface of the composite substrate by sputters and then by forming a final transparent electrode layer on the first layer by sputtering from the same target by applying thereto a higher electric power from the same DC power source. This method makes it possible to easily form a high quality transparent electrode layer for a solar cell at a high speed and can thereby contribute to improving the productivity of thin-film compound semiconductor solar cells.

According to the transparent electrode layer forming method of the present invention, a transparent electrode layer of a thin-film compound semiconductor solar cell can be formed by DC sputtering from a pair of oppositely disposed targets of the same material with no fear of sputter damage. Thus, this method makes it possible to easily produce a high-quality transparent electrode layer of a solar cell at a high speed.

According to the transparent electrode layer forming method of the present invention, a transparent electrode layer of a thin-film compound semiconductor solar cell can be formed by DC sputtering from a pair of oppositely disposed targets of the same material by changing the electric power to the targets from a low DC current to a high DC current, thus achieving easy and high speed formation of a high-quality transparent electrode layer of the solar cell with no fear of damaging the substrate by sputters.

According to the transparent electrode layer forming method of the present invention, a transparent electrode layer of a thin-film compound semiconductor solar cell can be formed by the first process of DC sputtering from a pair of oppositely disposed targets of the same material and by the second process of high-speed DC sputtering from a single target, thus achieving easy and high speed formation of a high-quality transparent electrode layer of the solar cell with no fear of damaging the substrate by sputters.

1. A transparent electrode layer forming method of forming a transparent electrode layer of a thin film compound semiconductor solar cell by a sputtering method, wherein the transparent electrode layer is formed by two direct-current sputtering processes: the first process forms a precursory layer having a thickness in a range of 650 Å to 1500 Å by applying a specified low electric power to a target and the second process forms a complete transparent electrode layer by applying a specified high electric power to the same target.

2. A transparent electrode layer forming method as defined in claim 1, characterized in that the low electric power to be supplied to the target in the first direct-current sputtering process is of 0.6 to 2.1 W per 1 cm² of the target surface and the high electric power to be supplied to the target in the second direct-current sputtering process is of 2.1 to 10.4 W per 1 cm² of the target surface.

3. A transparent electrode layer forming method as defined in claim 1, characterized in that the first sputtering process forms the precursory layer of having a thickness smaller than that of a final layer deposited by the second sputtering process.

4. A transparent electrode layer forming method as defined in claim 1, characterized in that a substrate having a molybdenum (Mo) electrode layer, a p-type light-absorbing layer and a n-type buffer layer formed thereon subsequently in the described order is used as a base material and a transparent electrode layer of ZnO group is formed on the buffer layer of the substrate by using a target of ZnO:X (with X being Ga, Al, In or B) group material.

5. (canceled)

6. (canceled)

7. (canceled)

8. (canceled)

9. (canceled)

10. (canceled)

11. A transparent electrode layer forming method of forming a transparent electrode layer of a thin film compound semiconductor solar cell by a sputtering method, wherein the transparent electrode layer is formed by two processes: a first process forms a precursory layer having a thickness in a range of 650 Å to 1500 Å by sputtering from a pair of oppositely disposed targets of the same material and a second process forms a complete transparent electrode layer by dc sputtering from a single target by supplying thereto high electric power.

12. (canceled)

13. (canceled)
